(19) United States
(12) Patent Application Publication
(10) Pub. No.: US 2018/0241211 A1
(43) Pub. Date: Aug. 23, 2018

(54) MULTIFUNCTIONAL POWER CORRECTION DEVICE

(71) Applicant: United Technologies Corporation, Farmington, CT (US)

(72) Inventors: Kaiyu Wang, Vernon, CT (US); Moon C. Kim, Glastonbury, CT (US)

(21) Appl. No.: 15/751,629

(22) PCT Filed: Sep. 2, 2015
(86) PCT No.: PCT/US2015/048024

§ 371 Date: Feb. 9, 2018

(51) Int. Cl. H02J 3/18; H02M 7/44; H02M 1/42; G01R 21/00

(52) U.S. Cl. CPC H02J 3/18; H02M 7/44; G01R 21/003; G01R 21/002; H02M 1/4208

(57) ABSTRACT

A power factor correction system according to the present disclosure includes an inverter connected in parallel with at least one load and a controller configured to command an output voltage of the inverter to provide reactive power to the at least one load when a voltage source is available to the load and real power and reactive power to the at least one load when the voltage source is unavailable to the load.

### BACKGROUND

The power factor of an AC electric power system is the ratio of the real power flowing to the load to the apparent power, which is the product of the current and voltage of the circuit. In an AC electric power system, a load with a low power factor draws more current from the power source than a load with a high power factor draws for the same amount of useful power transferred. The higher currents in a system having a low power factor increase losses and decrease efficiency. A utility company may set a minimum power factor requirement for its customers, usually 0.85 to 0.95. There are challenges associated with increasing the power factor for AC electric power systems.

### SUMMARY

A power factor correction system according to the present disclosure includes an inverter connected in parallel with at least one load and a controller configured to command an output voltage of the inverter to provide reactive power to the at least one load when a voltage source is available to the load and real power and reactive power to the at least one load when the voltage source is unavailable to the load.

In a further embodiment of any of the foregoing embodiments, the controller is configured to command a magnitude and a phase angle of the output voltage of the inverter when the voltage source is unavailable to the load.

In a further embodiment of any of the foregoing embodiments includes a meter in communication with the voltage source, the controller is configured to command the phase angle of the output voltage of the inverter based upon a real power reference value signal from the meter indicative of the real power being provided by the voltage source and a real power output measurement from the inverter indicative of the real power being output by the inverter.

In a further embodiment of any of the foregoing embodiments, the controller is configured to command the magnitude of the output voltage of the inverter based upon a reactive power reference value signal from the meter indicative of the reactive power being provided by the voltage source and a reactive power output measurement from the inverter indicative of the reactive power being output by the inverter.

In a further embodiment of any of the foregoing embodiments, the voltage source is a utility source.

In a further embodiment of any of the foregoing embodiments includes a meter that provides an indication of real and reactive power values to the controller.

In a further embodiment of any of the foregoing embodiments, the controller commands the output voltage of the inverter based upon the real and reactive power values provided by the meter.

In a further embodiment of any of the foregoing embodiments, at least one load is an inductive load.

A method of controlling a power factor in a power system according to an example of the present disclosure includes, providing an inverter in parallel with at least one load, an output voltage of the inverter providing reactive power to the at least one load based on when a voltage source is available to the at least one load and the output voltage of the inverter providing real and reactive power to the at least on load based on when the voltage source is not available to the at least one load.

In a further embodiment of any of the foregoing embodiments includes, providing a controller in communication with the inverter and a power meter associated with the voltage source.

In a further embodiment of any of the foregoing embodiments includes, commanding the output of the voltage of the inverter to provide real and reactive power to the at least one load by commanding a magnitude and a phase angle of the output of the inverter.

In a further embodiment of any of the foregoing embodiments, the phase angle of the output voltage of the inverter is commanded based upon a real power reference value signal from a power meter indicative of the real power being provided by the voltage source and a real power output measurement from the inverter indicative of the real power being output by the inverter.

In a further embodiment of any of the foregoing embodiments, the magnitude of the output voltage of the inverter is commanded based upon a reactive power reference value signal from the power meter indicative of the reactive power being provided by the voltage source and a reactive power output measurement from the inverter indicative of the reactive power being output by the inverter.

In a further embodiment of any of the foregoing embodiments, at least one load is an inductive load.

The various features and advantages of disclosed embodiments will become apparent to those skilled in the art from the following detailed description. The drawings that accompany the detailed description can be briefly described as follows.

### BRIEF DESCRIPTION OF THE DRAWINGS

FIG. 1 schematically illustrates an example microgrid power system.

FIG. 2 schematically illustrates an example inverter control algorithm.

### DETAILED DESCRIPTION

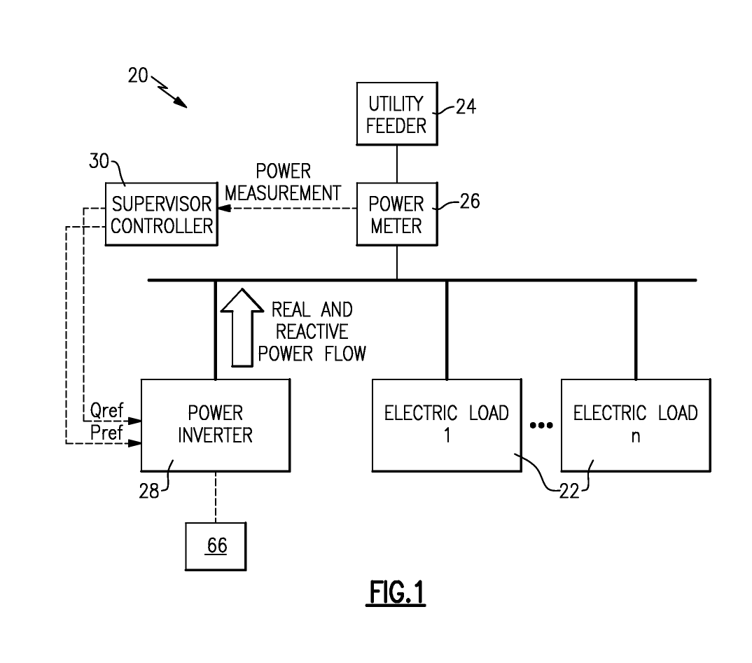

FIG. 1 schematically shows a microgrid power system 20. A plurality of loads 22 are arranged in parallel and connected to a utility source 24 for supplying electrical power to the loads 22. A power meter 26 is arranged between the utility source 24 and the loads 22 and measures the power input into the power system 20 from the utility source 24.

A power inverter 28 is arranged in parallel with the loads 22. In the illustrated example, the loads 22 include inductive loads requiring both real and reactive power supply for operation. The power inverter 28 is in communication with a supervisor controller 30, which is in communication with the power meter 26. The power inverter 28 provides real and reactive power to the loads 22. As is known, the portion of power that, averaged over a complete cycle of the AC waveform, results in net transfer of energy in one direction is known as real power. The portion of power due to stored energy, which returns to the source in each cycle, is known as reactive power.

The inverter 28 serves as a power factor correction device. It provides the reactive power to the inductive loads, reducing the amount of reactive power required to be provided by the utility source 24 to power the loads and thus improving the power factor of the loads 22 apparent to the utility source 24.

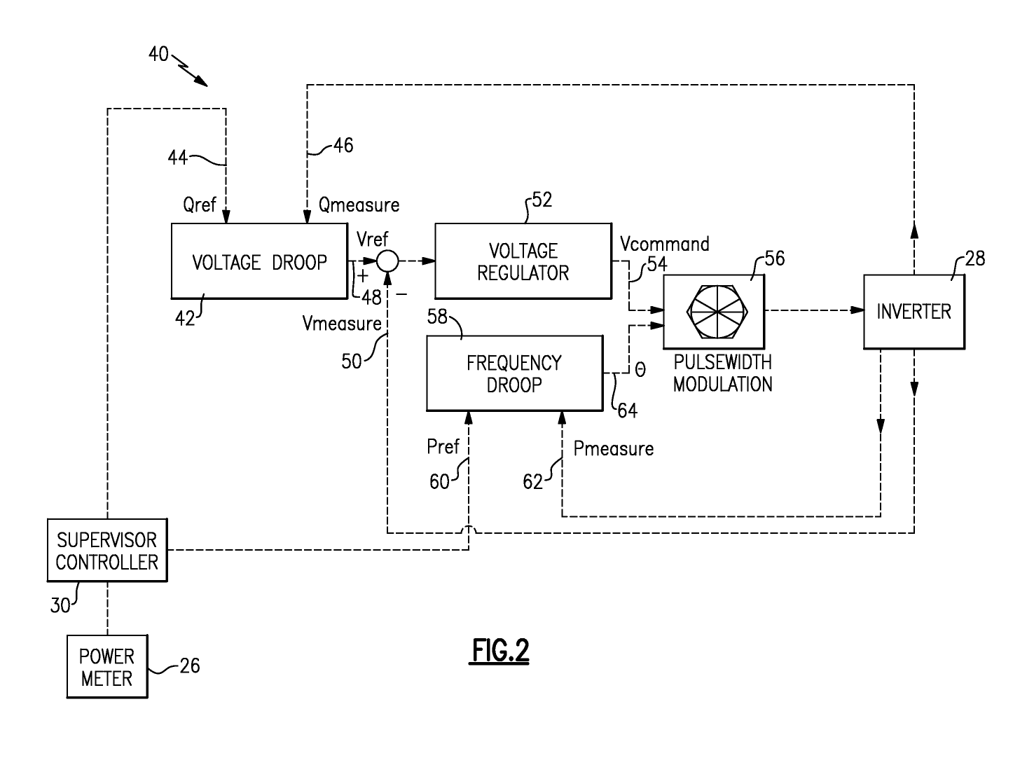

FIG. 2 schematically shows a control algorithm 40 for the inverter 28. The supervisor controller 30 uses the control algorithm 40 to command the output voltage of the inverter 28. The Voltage Droop module 42 receives a reactive power reference signal 44 (Qref) from the utility meter 26 indicative of the reactive power output by the utility source 24 and a measured reactive power inverter output signal 46 (Qmeasure) from the inverter 28 indicative of the reactive power output at the inverter 28. The Voltage Droop module 42 outputs a reference voltage signal 48 (Vref). The reference voltage signal 48 is calculated based on the following formula:

V_{ref}=C+K(Q_{ref}−Qₘₑₐₛᵤᵣₑ)

where C and K are constants that are set using a rated voltage and a maximum allowable voltage deviation.

The reference voltage signal 48 is compared with a measured voltage signal 50 (Vmeasure), which is the measured output voltage at the inverter. The measured voltage signal 50 is usually received from a sensor at the inverter 28 output, while the measured reactive power inverter output signal 46 may be calculated using the measured voltage signal 50 and a measured current value. The difference between the reference voltage signal 48 and the measured voltage signal 50 is input to a Voltage Regulator module 52. The Voltage Regulator module 52 provides a voltage command signal 54 (Vcommand) to a pulsewidth modulation module 56. The voltage command signal 54 is calculated by the voltage regulator module 52 based on the difference between the reference voltage signal 48 and the measured voltage signal 50. The calculation of the voltage command signal 54 in the voltage regulator module 52 may use proportional-integral control—a control loop feedback method for making the measured voltage signal 50 track the reference voltage signal 48.

A frequency droop module 58 receives a real power reference value signal 60 from the utility meter 26 and an inverter real power output signal 62 from the inverter 28 indicative of the real power output at the inverter 28. The frequency droop module 58 outputs a phase angle 64 to the pulsewidth modulation module 56, which sends the appropriate voltage magnitude and phase angle command, forming an alternating current waveform, to the inverter 28. The inverter 28 thus adjusts the magnitude and phase angle of its output voltage, in response to the command from the supervisor controller 30, to provide real and reactive power to the loads 22.

The modules 42, 52, 56, and 58 may be software algorithms implemented in micro-controllers or micro-processors.

By carefully controlling the magnitude and phase angle of the output voltage at the inverter 28, the inverter 28 can supply real and reactive power to the system. This is because the real power from the inverter 28 to the loads 22 is significantly affected by the phase angle of the output voltage, and the reactive power output by the inverter 28 is significantly affected by the magnitude of the output voltage. Real power (P) is equal to:

$$P = \frac{{V}_{1} {V}_{2}}{X} sin δ$$

Reactive power (Q) is equal to:

$$Q = \frac{{V}_{2}}{X} ( {V}_{2} - {V}_{1} cos δ )$$

Because the power angle δ is small, the equations can be simplified into:

$$δ \approx \frac{PX}{{V}_{1} {V}_{2}} and \\ ( {V}_{2} - {V}_{1} ) \approx \frac{QX}{{V}_{2}}$$

Thus, real power is largely influenced by the phase angle and reactive power is largely influenced by the voltage magnitude. By precisely controlling both the phase angle and the magnitude of the output voltage of the inverter 28, the inverter 28 may supply both real and reactive power to the system.

Traditional power factor correction devices, such as capacitor banks or static synchronous compensators (STATCOM), only inject reactive power into the system. These devices operate in a “current control” mode, where the current output by the devices is what is controlled. The inverter 28, when commanded by the supervisor controller 30 based on control algorithm 40, is multifunctional in that the inverter 28 provides both real and reactive power to the loads 22. It is able to supply both real and reactive power because it is commanded in “voltage mode,” i.e., the voltage output of the inverter 28, and particularly the magnitude and phase angle of the voltage output, are controlled and commanded.

Moreover, because the inverter 28 is controlled in voltage mode, a seamless transition may be achieved when a primary voltage source, the utility source 24 in the example, is not connected to the system. This condition may be known as “islanding mode.” With traditional power factor correction devices that operate under “current control” mode, the control system must switch to a voltage control mode when the voltage source is lost, creating a large transient on the system. Because the inverter 28 is already operating in a voltage-based mode during grid connected mode, a seamless transition with a small transient from grid-connected mode to islanding mode can be achieved. The inverter 28 can continue to supply both real and reactive power to the loads 22 during islanding mode. The inverter 28 may be connected to a source 66 (shown schematically in FIG. 1), such as a storage unit or alternative power generator, for supplying electrical power to the system when the utility voltage source 24 is not connected.

Experimental results of an example implementation of the multifunctional power factor correction inverter 28 commanded by the supervisor controller 30 using control algorithm 40 demonstrate an improved power factor. For example, without using the inverter 28, the reactive power value (Q) at the utility meter 26 was 0.004 MVar. For example, when the inverter 28 is used, the reactive power value (Q) at the utility meter 26 was 0.000 MVar.

The preceding description is exemplary rather than limiting in nature. Variations and modifications to the disclosed examples may become apparent to those skilled in the art that do not necessarily depart from the essence of this disclosure. Thus, the scope of legal protection given to this disclosure can only be determined by studying the following claims.

We claim:

1. A power factor correction system comprising:
an inverter connected in parallel with at least one load; and
a controller configured to command an output voltage of the inverter to provide reactive power to the at least one load when a voltage source is available to the load and real power and reactive power to the at least one load when the voltage source is unavailable to the load.

2. The system as recited in claim 1, wherein the controller is configured to command a magnitude and a phase angle of the output voltage of the inverter when the voltage source is unavailable to the load.

3. The system as recited in claim 2, comprising
a meter in communication with the voltage source,
wherein the controller is configured to command the phase angle of the output voltage of the inverter based upon a real power reference value signal from the meter indicative of the real power being provided by the voltage source and a real power output measurement from the inverter indicative of the real power being output by the inverter.

4. The system as recited in claim 3, wherein the controller is configured to command the magnitude of the output voltage of the inverter based upon a reactive power reference value signal from the meter indicative of the reactive power being provided by the voltage source and a reactive power output measurement from the inverter indicative of the reactive power being output by the inverter.

5. The system as recited in claim 1, wherein the voltage source is a utility source.

6. The system as recited in claim 5, comprising a meter that provides an indication of real and reactive power values to the controller.

7. The system as recited in claim 6, wherein the controller commands the output voltage of the inverter based upon the real and reactive power values provided by the meter.

8. The system as recited in claim 1, wherein the at least one load is an inductive load.

9. A method of controlling a power factor in a power system, comprising:
providing an inverter in parallel with at least one load;
an output voltage of the inverter providing reactive power to the at least one load based on when a voltage source is available to the at least one load; and
the output voltage of the inverter providing real and reactive power to the at least one load based on when the voltage source is not available to the at least one load.

10. The method as recited in claim 9, comprising:
providing a controller in communication with the inverter and a power meter associated with the voltage source.

11. The method as recited in claim 9, comprising commanding the output voltage of the inverter to provide real and reactive power to the at least one load by commanding a magnitude and a phase angle of the output voltage of the inverter.

12. The method as recited in claim 11, wherein the phase angle of the output voltage of the inverter is commanded based upon a real power reference value signal from a power meter indicative of the real power being provided by the voltage source and a real power output measurement from the inverter indicative of the real power being output by the inverter.

13. The method as recited in claim 12, wherein the magnitude of the output voltage of the inverter is commanded based upon a reactive power reference value signal from the power meter indicative of the reactive power being provided by the voltage source and a reactive power output measurement from the inverter indicative of the reactive power being output by the inverter.

14. The method as recited in claim 9, wherein the at least one load is an inductive load.
